(19) United States
(12) Patent Application Publication
(10) Pub. No.: US 2002/0139662 A1
(43) Pub. Date: Oct. 3, 2002

(54) Thin-film deposition of low conductivity targets using cathodic ARC plasma process

(76) Inventor: Brent W. Lee, San Jose, CA (US)

Correspondence Address: Bo-In Lin, 13445 Mandoli Drive, Los Altos Hills, CA, 94022, US

(21) Appl. No.: 09/791,438

(22) Filed: Feb. 21, 2001

(51) Int. Cl. C23C 14/00

(52) U.S. Cl. 204/192.38; 204/298.41; 204/298.12; 204/298.13

(57) ABSTRACT

This invention discloses a cathodic arc deposition apparatus for depositing a layer of low-conductivity material on a surface of a substrate. The cathodic arc deposition apparatus includes a source contained in a vacuum chamber. The source further includes a target mount for mounting a target thereon wherein the target comprising fused mixture of powders of the low-conductivity material hot-pressed with powders of a high conductivity material functioning as conductivity-enhancement matrix. The cathodic arc deposition apparatus further includes an electric arc for striking the target to evaporate a plurality of ions of the low conductivity material and the high conductivity material. The cathodic arc deposition apparatus further includes an ion trajectory guiding means for guiding the ions for projecting to the substrate contained in the vacuum chamber. The cathodic arc deposition apparatus further includes an ion shielding means for selective shielding ions of the conductive material for depositing only the ions of the low-conductivity material on the substrate.

### BACKGROUND OF THE INVENTION

1. Field of the Invention

This invention relates generally to apparatus and method for deposition of low conductivity and insulation material by employing cathodic arc deposition and magnetic sputtering technologies. More particularly, this invention is related to a new apparatus and process applying cathodic arc deposition technology to deposit low-conductivity or non-conductive thin films of silicon, LiPO4 etc, and to use the technique for manufacturing electrolyte for solid-state thin-film lithium ion batteries.

2. Description of the Prior Art

Even that cathodic arc deposition is well known in the art for depositing layers of thin film composed of target materials on a substrate, the technology is however mostly limited to deposition of target materials with characteristics of high electrical and thermal conductivity. Issued patents such as U.S. Pat. Nos. 4,556,471 and 4,622,452 disclosed cathodic arc deposition systems are incorporated by reference herein as though set forth in full. The technologies cannot be conveniently employed for depositing target materials of low electrical and thermal conductivity or insulating materials. Target materials used in the prior art systems are usually materials such as chromium, titanium and other metals and alloys with similar material properties. Target materials that have low electrical conductivity and therefore generally having low thermal conductivity are not ideal target materials for cathodic arc deposition techniques. Because the electric arc does not properly strike and the arc does not sustain over the target material composed of low conductivity.

The manufacturing techniques for some low electric conductivity materials used in the prior art have included the use of highly doped materials then heating the target material in order to increase its electrical conductivity and by embedding thin wires of conductive materials with the target material. Each of these methods has its drawbacks. In the case of wire implanted target material, the arc struck current through the wires producers such heat as to melt the surrounding target material in an attempt to sustain. Also, the arc tends to become stationary in a single spot to form a large crater, rather than moving properly the target material. Therefore, the utilization of the target material is low. Additionally, because of the thermal conductivity of the target is poor, the target material becomes unevenly heated and tends to crack due to the localization of the heat from the arc in a single spot, sometimes causing the target to disintegrate.

Furthermore, there are technical difficulties encountered in forming thin-film layers of electrolyte for lithium ion solid-state thin-film battery because the electrolyte has low electric and thermal conductivity. Conventional method of forming electrolyte layers for lithium ion solid state batteries applying a magnetron sputtering process. Specifically, several prior art Patents including U.S. Pat. Nos. 5,597,660, 5,654,084, 5,512,147, 5,338,625, 5,314,765 disclosed magnetic sputtering processes to form the electrolyte for lithium ion solid state batteries. Such processes are limited by a low rate of layer formation thus the electrolyte layers are formed very slowly. Due to this limitation, thin-film lithium ion solid-state batteries become very expensive and cannot be economically produced.

Therefore, a need still exists in the art of cathodic arc deposition to provide a new and improved process and target material composition to overcome these difficulties and limitations.

### SUMMARY OF THE PRESENT INVENTION

It is therefore an object of the present invention to provide new and improved process and target material composition that is primarily composed of a material having low electrical and thermal conductivity and insulating materials. Meanwhile, the target material can performs well in a cathodic arc deposition system such that the difficulties and limitations in applying cathodic arc technology for low electrical conductivity target commonly encountered in the prior art can be resolved.

Specifically, it is an object of the present invention to provide a new and improved process and target materials by providing a mixture of powdered high conductivity material and powdered low conductivity target material. The mixture is then mechanically hard pressed and then heated as a mixed and pressed, i.e., fused, conductivity-enhanced target material. The fused target provides characteristics of improved electrical and thermal conductivity such that the target performs well in the cathodic arc deposition processes. These conductive particles, e.g., the aluminum particles, disposed in the target can present a separate arcing spot such that multiple arcs are sustained and transmitted throughout the face of the target to enhance an even utilization of the entire target. As a result, all the particles are evenly evaporated from the arc spots and more even distribution of heat is generated with reduced likelihood of target cracks and disintegration.

It is another object of the present invention to provide a new and improved process and target material to form electrolyte layers for the thin-film lithium-ion solid batteries with higher formation rate. The method of applying conductivity enhanced target by mixing and fusing the low-conductivity electrolyte powders of conductive enhanced powders. The conductivity enhanced electrolyte target is then used in a cathodic arc deposition apparatus to form the electrolyte layers for a solid-state batteries to greatly increase the rate of layer formation thus reduce the cost and increase the availability of lithium ion solid-state batteries.

Briefly, in a preferred embodiment, the present invention discloses a conductivity-enhanced target for a cathodic arc deposition chamber. The conductivity-enhanced target includes a fused mixture of low-conductivity target powder hot-pressed with conductivity-enhancement high conductivity powder. In a preferred embodiment, the target includes fused mixture of LiPO4 powder hot-pressed with aluminum powder functioning as the conductivity-enhancement high conductivity powder. In one particular embodiment, the target includes a fused mixture of approximately 90% weight percentage of LiPO4 and approximately 10% of the aluminum powder. In one preferred embodiment, the target is mounted on an electrically conductive target mount having channels for passing coolant to cool the conductive target mount. In one embodiment, the target mount is disposed in a vacuum chamber with magnetic filter for selectively passing different ions.

In summary this invention discloses a method for depositing a low conductivity material on a surface of substrate. The method includes a step of forming a conductivity-enhanced target by fusing a mixture of low-conductivity target powder with conductivity-enhancement high conductivity powder using a hot-press process. The method further includes mounting the conductivity-enhanced target on a target mount of a cathodic arc chamber for applying a cathodic arc deposition process for depositing the low conductivity material on a substrate.

These and other objects and advantages of the present invention will no doubt become obvious to those of ordinary skill in the art after having read the following detailed description of the preferred embodiment which is illustrated in the various drawing figures.

### BRIEF DESCRIPTION OF THE DRAWINGS

FIG. 1 is a side cross sectional view of a target mount for mounting a target of this invention;

FIG. 2 is a side cross-sectional view of a substrate has an organic material film layer, a thin film layer of low conductivity of this invention covered by a metallic layer; and

FIG. 3 a side cross-sectional view of vacuum chamber comprising a magnetic filter for carrying out a cathodic arc deposition for depositing a low conductivity material of this invention.

### DETAILED DESCRIPTION OF THE PREFERRED EMBODIMENT

The present invention is directed to a process involving the steps of first forming a conductivity-enhanced target by mixing and hot pressing then fusing target materials of low electric conductivity with conductivity-enhancement materials such as aluminum. The conductivity-enhanced targets are formed to have the material characteristics that the electrical conductivity and thermal conductivity are about the same as that of titanium. As will be discussed below, such conductivity-enhanced targets perform very well for a cathodic arc deposition process. Aided by the conductivity enhancing matrix materials, deposition of low conductivity targets is carried out with the conductivity-enhanced targets applied in a cathodic arc chamber.

More specifically, for cathodic arc deposition operation, researches are performed to determine certain types of conductivity-enhanced targets that would be suitable for cathodic arc deposition. As the results of researches conducted by the Applicant of the present invention, it is determined that there are generally three types of materials as that shown in Table 1. The choices of target materials, according to this invention, can be more specifically understood by examining the material characteristics of three groups of materials as that presented in Table 1. The target materials that achieve the best performance includes titanium, zirconium, and chromium as found in the first group. The cathodic arc deposition process carried out in a vacuum chamber when performed with the targets in the first group of Table 1 is stable, easy to control and produces relatively small quantity of macro-particles. These metals have modest prices but can provide high commercial value because the melting point is between 1450 to 2000 degrees Celsius with medium thermal and electrical conductivity.

The second group of elements consists of materials having a low melting point typically less than 1000 degrees Celsius with high thermal conductivity. The arc spot generally moves slowly and may create a puddle spot of melted material. Also, in the process of layer formation by applying the cathodic arc deposition, a large quantity of macro-particles are spit out which is not desirable. Some of the materials such as gold and silver are more expensive. Furthermore, the most significant drawback is the large size of the macro-particles. Elements such as Zn, Cd, Sn and Pb have even lower melting point and generate larger quantity of macro-particles and would therefore not useful to make these materials as targets. The third group of elements consists of high melting point materials around 2500 degree Celsius. These types of materials produce lower quantities of macro-particles. However, the arc process is less stable and more difficult to control. Also, the material cost is generally higher for this group of elements. Mixtures of Group II and Group III materials may provide mixed target materials having performance characteristics similar to that of Group I materials.

Another technique to provide material compositions having target performance characteristics and physical properties of Group I is to use the conductivity-enhancing matrix. The conductivity-enhancing matrix is formed with a novel method of this invention. Specifically, materials such as aluminum or other conductive materials are mixed with low conductivity target materials to produce a composition with the electrical and thermal conductivity of the target approximately the same as that of titanium. One example of such composition is to combine tantalum, silicon, LiPO4, or other substantially nonconductive materials or compounds with highly conductive metals such as copper, aluminum or other compounds of high conductivity, in appropriate percentage. The mixture are employed to produce a target having thermal and electrical conductivity similar to that of a titanium target.

As depicted in FIG. 1, a target 14 is mounted on a target mounting-base 26 via an adhesive layer 20. The target 14 is a conductivity-enhanced target such as the silicon-aluminum target or a LiPO4-aluminum target. The processes for manufacturing such targets will be further discussed below. The mounting base 16 is preferably composed of a material of high electrical and thermal conductivity such as copper. The mounting base 16 is engaged to a cathode base 24. A coolant flow chamber 32 with inlet line 36 and outlet line 40 is formed in the cathode base 24 to cool the target 14 by conducting heat away generated from the target in the process of arcing. An O-ring seal 44 is formed in the outer edge of the cathode base 24 to form a watertight seal between the target mounting base 16 and the cathode base 24. The target-mounting base is only one of several possible different embodiments. Any cathode-mounting base as that disclosed in the prior art may be suitable for this invention.

In a preferred embodiment of utilizing a silicon-aluminum target, a target having a diameter of about 3 inches is exposed to a DC current of approximately 30 amperes at a voltage about 20-40 volts. The cost of electricity consumption is therefore quite low in forming the thin film coatings. The deposition rate of silicon film is in the order of one micrometer per minute. The silicon film so formed has many different applications in electronic and semiconductor industries. Further implementations of the silicon-aluminum target can be performed in an oxygen enriched deposition chamber to form a thin film composed of silicon dioxide SiO2 layer. The required quantity of oxygen in the chamber is primarily dependent on the rate at which the silicon is evaporated from the target in the cathodic arc process. Basically, the flow rate of oxygen in the chamber must be sufficient to bond with the silicon evaporated from the target in order to form the silicon dioxide thin film. The silicon dioxide layer film is transparent, hard and corrosive resistant. The aluminum component when oxidized as aluminum oxide is also transparent and optically compatible with the silicon dioxide in forming a transparent corrosive resistive layer. For these reasons, aluminum is a preferred conductive enhancement and fusing element in forming the silicon-aluminum target to form the silicon dioxide layer. Substrates composed of brass, chromium and polycarbonate materials constitute significant applications for silicon dioxide films. Also, the silicon dioxide thin films have significant applications in the electrical and semiconductor manufacturing industries.

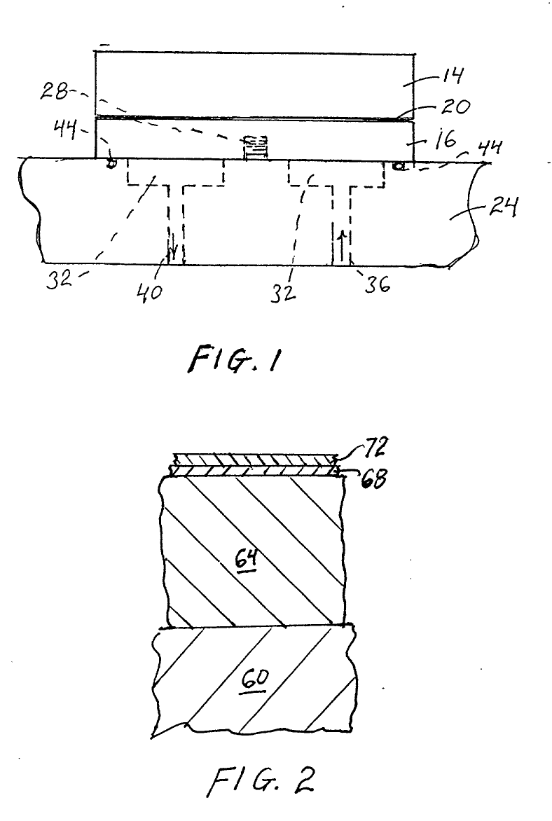

In addition to the oxygen chamber as described above, nitrogen gas can also be provided to form thin film composed of silicon nitride, again of broad industrial applications. For thin film with higher level of hardness, a thin film deposition filled with gas of CH4, or C2H2 can be implemented to form silicon carbide layers. The films composed of silicon oxide, silicon nitride, or silicon carbide, have characteristics fall between those of metal films and those of organic material films, for this reasons, they are able to bond well to both organic material films and metal films. Therefore, the silicon, silicon oxide, silicon nitride and silicon carbide films of the present invention can serve as good barrier or bonding layers between films composed of organic materials and metal films. As depicted in FIG. 2, a substrate 60 has an organic material film layer 64 deposed on the to surface. A thin film layer 68 of low conductivity of this invention, composed of silicon, silicon dioxide, silicon nitride or silicon carbide is deposited on the organic material layer 64. Then, a metallic film 72 is deposited on the layer 68. The layer 68 of this invention serves as a bonding or barrier layer between the metal layer 72 and the organic material layer 64. In particular applications, the organic material layer may consist of various organic polymers, sol-gel paint, paint powder and film of composed of similar materials. This type of coating layer 64 may have a thickness of approximately one to fifty microns that is capable of covering surface imperfections of the substrate 60. The thin film coating 68 of the present invention as composed silicon, or silicon oxide, nitride or carbide, is then deposited on the organic film using the cathodic arc plasma technology to a thickness of approximately 0.5 microns. The coating layer 68 bonds well to the surface of the organic-material-layer 64 and provides a generally hard physical barrier. The top coating 72 may consist of a metal layer such as chromium, titanium nitride, zirconium nitride, and layers composed of similar kinds of materials. In addition to the good bonding characteristics, the layer 68 provides attractive color and provides sufficient hardness to resist structure degradation and corrosion for long term applications.

For the purpose of forming solid-state lithium ion battery-electrolyte layer, an insulation material is formed by mixing powers of lithium (Li) and PO4 and then mixed with aluminum powders. Hot press of the powder mixture is carried out in a vacuum chamber by using an inductive heat. The aluminum powders act as tightly connected matrix between the LiPO4 powders to solidify the mixture and forming a conductive enhanced target with the lithium fused with the LiPO4 with aluminum or other conductive powder particles acting as conductive fusing matrix. With the electrical and thermal conductive enhancing powder particles now fused between the LiPO4 particles, the target becomes suitable target for application in an cathodic arc deposition system to form the electrolyte layers at significantly increased formation rates. The target composition may contain a 90% weight percentage of LiPO4, and 10% weight percentage of aluminum or other conductive enhancing and fusing agents such as cooper or other types elements or alloys. Just like that shown in FIG. 1, the LiPO4—Al target is mounted on a copper-mounting base and then operated according to that described above.

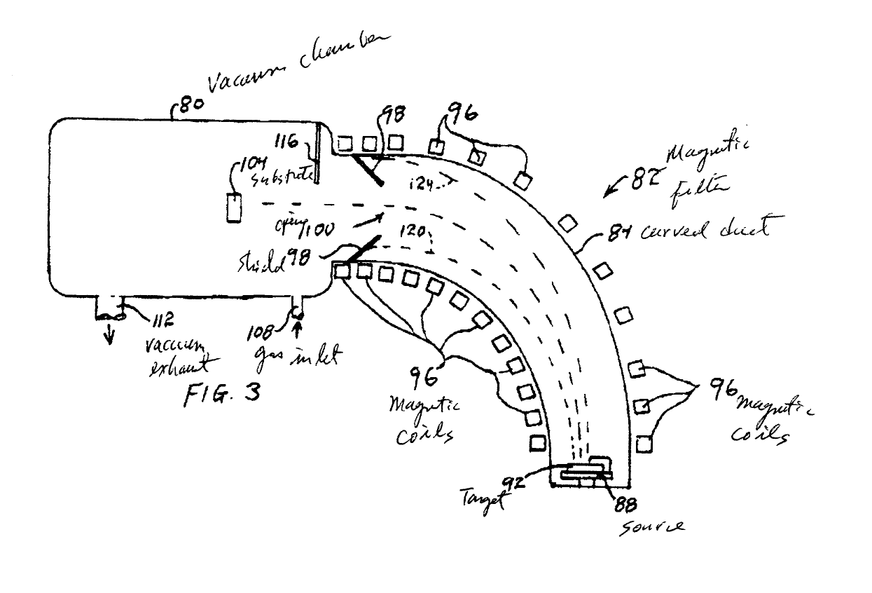

As described above, the target is composed of both non-conductive and conductive materials such as silicon target that includes a small amount of aluminum, or a LiPO4 target that includes a small amount of aluminum. The cathodic arc deposition process is applied to evaporate the non-conductive and conductive ions. In some applications, it is desirable to filter out more coarse particles to obtain a surface layer comprising only fine particles of the target, e.g., LiPO4. The cathodic arc deposition process must then provide a method to prevent macro particles to reach the surface of the substrate. FIG. 3 depicts a vacuum chamber equipped with a magnetic filter that is designed to separate the different ion species. FIG. 3 shows a vacuum chamber 80 that includes a magnetic filter 82. The filter 82 includes a curved duct 84 engaged to a wall of the chamber 80. A catholic arc source 88 that includes a target 92 may be a silicon or LiPO4 target mixed with aluminum or other conductive materials as conductivity-enhancement matrix. A plurality of magnetic coils 96 are disposed exterior to the curved duct 84 such that a controlled magnetic field is produced within the duct 84. Shields 98 which may be controllable are disposed within the duct to provide a controllable narrow opening 100 between the shield 98 for the passage of ions from the target 92 through the opening 100.

A substrate 104 is disposed within the chamber 80 for depositing particles generated from the target 92. The substrate 104 may be stationary mounted on a rotating platform or a moving film that is activated by an appropriate mechanism such as a biasing voltage may be applied to the substrate as that known in the art. A gas inlet 108 and vacuum exhaust 112 are engaged to the chamber such that reactive gases, e.g., argon, nitrogen, oxygen and other gases as discussed above can be introduced into the vacuum chamber. The reactive gases will form compounds such as oxide, nitride, carbides or other types of compounds of the non-conductive target materials to form a thin film on the substrate. The chamber may also equipped with a sensor 116 to detect the ion species that pass through the curved duct 84 toward the substrate 104.

In operation, the trajectory of each ion species emanated from the target 92 can be controlled by the magnetic field generated by the coils 96 as that known in the art. Generally, ions having a low mass will have a trajectory 120 with a relatively small radius of curvature as compared to ions having a higher mass having a trajectory 124 with a larger radius of curvature within the same magnetic field. Therefore, by adjusting the current in the magnetic coils 96, the strength of the magnetic field is controlled and the trajectory of the ion species emanating from the target 92 can be adjusted. Additionally, the opening 100 in the shields 98 can be controlled to block out unwanted ion species. The composition of the ions is therefore controllable by adjusting the magnetic field and the shield opening 100. The cathodic arc deposition is applied to deposit thin film composed of substantially precisely selected ions by properly controlling the magnetic field and the opening 100 of the shield. For the application of forming an electrolyte layer for implementation in a lithium ion thin-film solid state battery, a pure LiPO4 can be deposited by properly excluding the aluminum ions from reaching the substrate. The information as detected by the sensor 116 is used as feedback to the controller to adjust the current input to the magnetic coils in order to provide control of the composition of the ions that pass through the shield 98 to the substrate 104.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

TABLE I
The Physical Properties of Some Target Materials

| | | | | | | | Amount of | | |
|---|---|---|---|---|---|---|---|---|---|
| Group | | Special Weight | | **Thermal Conductivity | ***Resistivity | Minimum Amp to | Macro | Speed of | Stability of |
| Number | Element | g/cm⁻³ | *Mp ° C. | W/(mk) at 300K | μohm-cm at 300K | sustain arcing | Particles | Arcing | Arcing |
| I | Ti | 4.51 | 1,668 | 21 | 43 | 30-35 | Small | Fast | Good |
| | Cr | 6.92 | 1,510 | 90 | 13 | 30-35 | Small | Fast | Good |
| | Ni | 8.93 | 1,452 | 91 | 7 | 30-35 | Small | Fast | Good |
| | Zr | 6.5 | 1,850 | 23 | 41 | 50-55 | Small | Fast | Good |
| II | Ag | 10.7 | 962 | 424 | 1.6 | 30-35 | Large | Slow | Good |
| | ****Cu | 8.94 | 1,083 | 398 | 1.71 | 30-35 | Large | Slow | Good |
| | Au | 19.3 | 1,063 | 315 | 2.4 | 30-35 | Large | Slow | Good |
| | Al | 2.7 | 660 | 237 | 2.7 | 30-35 | Large | Slow | Good |
| III | W | 19.6 | 3,410 | 180 | 5.6 | 90-100 | Very | Fast | Difficult |
| | | | | | | | Small | | |
| | Mo | 10.2 | 2,610 | 138 | 5.6 | 90-100 | Very | Fast | Difficult |
| | | | | | | | Small | | |
| | Ta | 16.6 | 2,850 | 57 | 13 | 90-100 | Very | Fast | Difficult |
| | | | | | | | Small | | |

*Materials' Handbook (14 Edition) by George S. Brady etc.
**Engineering Manual (3rd Edition) by Robert H. Perry
***Handbook of Tables for A.E.S.
****Mechanical Engineers' Handbook, by Myer Kutz

I claim:

1. A cathodic arc deposition apparatus for depositing a layer of low-conductivity or non-conductive material on a surface of a substrate comprising:
a source contained in a vacuum chamber;
said source further includes a target mount for mounting a target thereon wherein said target comprising fused mixture of powders of said low-conductivity or non-conductive material hot-pressed with powders of a high conductivity material functioning as conductivity-enhancement matrix.

2 The cathodic arc deposition apparatus of claim 1 further comprising:
an electric arc striker for striking said target to evaporate a plurality of ions of said low conductivity material and said high conductivity material.

3. The cathodic arc deposition apparatus of claim 2 further comprising:
an ion trajectory guiding means for guiding said ions for projecting to said substrate contained in said vacuum chamber.

4. The cathodic arc deposition apparatus of claim 2 further comprising:
an ion shielding means for selective shielding ions of said conductive material for depositing only said ions of said low-conductivity material on said substrate.

5. The cathodic arc deposition apparatus of claim 3 wherein:
said ion trajectory guiding means further comprising a magnetic guiding means for magnetically guiding and projecting said ions onto said substrate.

6. The cathodic arc deposition apparatus of claim 1 further comprising:
a reactive gas means for introducing a reactive gas into said vacuum chamber for reacting with said ions of said low-conductivity material.

7. The cathodic arc deposition apparatus of claim 1 wherein:
said source further includes a target mount for mounting said target wherein said target mount further includes coolant channels for conducting coolant therein for cooling said target and said target mount.

8. The cathodic arc deposition apparatus of claim 1 wherein:
said target further comprising fused powder of LiPO4 as said low conductivity or non-conductive material.

9. The cathodic arc deposition apparatus of claim 1 wherein:
said target further comprising fused powder of silicon as said low conductivity or non-conductive material.

10. The cathodic arc deposition apparatus of claim 1 further comprising:
a controller for controlling said cathodic arc deposition apparatus.

11. A conductivity-enhanced target for implementing as source of thin film deposition comprising:
a fused mixture of powders of a low-conductivity target material mixed and hot-pressed with powders of a high-conductivity material functioning as a conductivity-enhancement matrix.

12 The conductivity-enhanced target of claim 11 wherein:
said low conductivity target further comprising fused powder of LiPO4.

13. The conductivity-enhanced target of claim 11 wherein:
said low conductivity target further comprising fused powder of silicon.

14. The conductivity-enhanced target of claim 11 wherein:
said high conductivity material further comprising aluminum.

15. The conductivity-enhanced target of claim 11 wherein:
said low conductivity target further comprising fused powder of LiPO4 with a weight percentage of approximately 90%, and said high conductivity material further comprising aluminum with a weight percentage of approximately 10%.

16 A method for depositing a low conductivity material on a surface of substrate comprising
forming a conductivity-enhanced target by fusing a mixture powders of said low-conductivity target with powders of a high conductivity material functioning as a conductivity-enhancement matrix.

17. The method of claim 16 wherein:
said step of fusing a mixture of powders of said low conductivity target further comprising a step of fusing a mixture of powders of LiPO4.

18. The method of claim 16 wherein:
said step of fusing a mixture of powders of said low conductivity target further comprising a step of fusing a mixture of powders of silicon.

19. The method of claim 16 wherein:
said step of fusing a mixture of powders of said high conductivity material further comprising a step of fusing a mixture of powders of aluminum.

20. The method of claim 16 wherein:
said step of fusing a mixture of powders of said low conductivity target further comprising a step of fusing a mixture of powders of LiPO4 with a weight percentage of approximately 90%, and said step of fusing a mixture of powders of said high conductivity material further comprising a step of fusing a mixture of powders of aluminum with a weight percentage of approximately 10%.
